(19) United States
(12) Patent Application Publication
(10) Pub. No.: US 2013/0299847 A1
(43) Pub. Date: Nov. 14, 2013

(54) SEMICONDUCTOR LIGHT EMITTING DEVICE AND METHOD FOR MANUFACTURING SAME

(71) Applicant: KABUSHIKI KAISHA TOSHIBA, Minato-ku (JP)

(72) Inventors: Hiroshi KATSUNO, Tokyo (JP); Yasuo Ohba, Kanagawa-ken (JP); Kei Kaneko, Kanagawa-ken (JP); Mitsuhiro Kushibe, Tokyo (JP)

(21) Appl. No.: 13/941,192

(22) Filed: Jul. 12, 2013

Related U.S. Application Data
(62) Division of application No. 12/400,236, filed on Mar. 9, 2009.

(30) Foreign Application Priority Data
Sep. 3, 2008 (JP) 2008-225453

(51) Int. Cl. H01L 33/32

(52) U.S. Cl. CPC H01L 33/32
USPC 257/76

(57) ABSTRACT

A semiconductor light emitting device includes: a laminated structure body including an n-type semiconductor layer, a p-type semiconductor layer and a light emitting layer provided between the n-type semiconductor layer and the p-type semiconductor layer; a first electrode connected to the n-type semiconductor layer and containing at least one of silver and a silver alloy; and a second electrode connected to the p-type semiconductor layer.

### CROSS-REFERENCE TO RELATED APPLICATIONS

This application is based upon and claims the benefit of priority from the prior Japanese Patent Application No.2008-225453, filed on Sep. 3, 2008; the entire contents of which are incorporated herein by reference.

### BACKGROUND OF THE INVENTION

1. Field of the Invention

This invention relates to a semiconductor light emitting device and a method for manufacturing the same.

2. Background Art

Light produced in a semiconductor light emitting device may be directly extracted outside the device, or may repeat reflection inside the semiconductor light emitting device, illustratively at the interface between the substrate and ambient air, and externally extracted from the device surface, the substrate surface, or the side surface of the device. Part of the light inside the device is absorbed by the n-side electrode having low reflection efficiency, which contributes to decreasing the light extraction efficiency. For increasing the light extraction efficiency, it is effective to extract the light emitted inside the device outside the device by ingenuity of a device shape and a reflection film or the like. On the other hand, the n-side electrode serving as an absorber inside the device needs to have a somewhat large area because of constraints on electrode design, such as wire bonding based on ball bonding, bump formation for a flip-chip, and reduction of voltage drop due to the contact resistance of the n-side electrode. In the case of the device combining the reflection film and the p-side electrode, the area of the reflection film can not be broadened without restraint because of constraints on electrode design, such as design of the light emitting area and the n-side electrode tradeoffs or the like.

JP-A 2000-031588(Kokai) discloses a technique for providing a semiconductor device made of nitride semiconductor having few crystal defects by forming a high-quality nitride semiconductor on a substrate. A layer having many crystal defects absorbs light emitted from the light emitting layer and causes loss. However, by using such techniques as disclosed in JP-A 2000-031588(Kokai), light emitted from the light emitting layer can be prevented from being absorbed inside the device.

### SUMMARY OF THE INVENTION

According to an aspect of the invention, there is provided a semiconductor light emitting device including: a laminated structure body including an n-type semiconductor layer, a p-type semiconductor layer, and a light emitting layer provided between the n-type semiconductor layer and the p-type semiconductor layer; a first electrode connected to the n-type semiconductor layer and containing at least one of silver and a silver alloy; and a second electrode connected to the p-type semiconductor layer.

According to another aspect of the invention, there is provided a method for manufacturing a semiconductor light emitting device, including: laminating an n-type semiconductor layer, a light emitting layer, and a p-type semiconductor layer on a substrate; removing a part of the p-type semiconductor layer and a part of the light emitting layer to expose a part of the n-type semiconductor layer; and forming a silver containing film containing at least one of silver and a silver alloy on the exposed n-type semiconductor layer and the p-type semiconductor layer.

### BRIEF DESCRIPTION OF THE DRAWINGS

FIGS. 1A and 1B are schematic views illustrating the configuration of a semiconductor light emitting device according to a first embodiment of the invention;

FIG. 2 is a schematic view illustrating the configuration of the semiconductor light emitting device according to the first embodiment of the invention;

FIGS. 3A to 3C are schematic sequential process cross-sectional views illustrating part of a method for manufacturing the semiconductor light emitting device according to the first embodiment of the invention;

FIGS. 4A and 4B are schematic views showing the structure of a semiconductor light emitting device of a comparative example;

FIG. 5 is a graph view illustrating the characteristics of the semiconductor light emitting device according to the first embodiment of the invention;

FIG. 6 is a schematic cross-sectional view illustrating the structure of a semiconductor light emitting device according to a second embodiment of the invention;

FIGS. 7A to 7C are schematic sequential process cross-sectional views illustrating part of a method for manufacturing the semiconductor light emitting device according to the second embodiment of the invention;

FIG. 8 is a schematic sequential process cross-sectional view following FIGS. 7A to 7C;

FIG. 9 is a schematic cross-sectional view illustrating the structure of a semiconductor light emitting device according to a third embodiment of the invention;

FIG. 10 is a flow chart illustrating a method for manufacturing a semiconductor light emitting device according to a fourth embodiment of the invention; and

FIG. 11 is a schematic view illustrating the configuration of a semiconductor light emitting apparatus according to a fifth embodiment of the invention.

### DETAILED DESCRIPTION OF THE INVENTION

Embodiments of the invention will now be described with reference to the drawings.

It is noted that figures are schematic and conceptual, the relationship between a thickness and a width of respective portions and size ratios between portions are not always identical with real ones. Even in the case where the same portions are shown, each other's dimensions and ratios may be shown differently depending on figures.

In the specification and respective figures, elements similar to those described with regard to previous figures are marked with the same reference numerals and not described in detail as necessary.

### First Embodiment

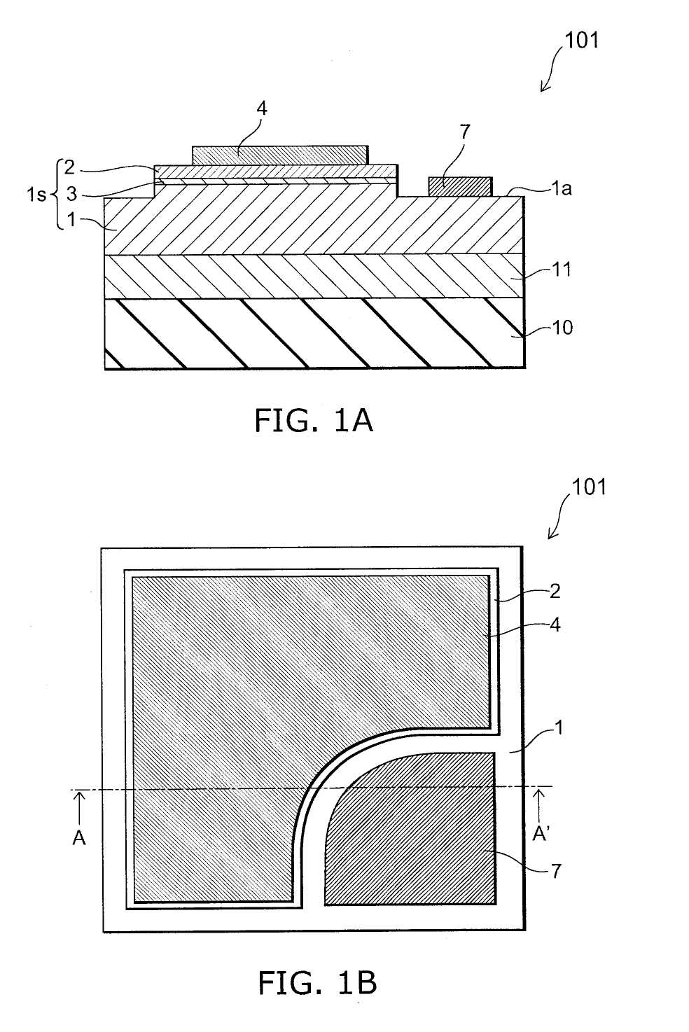

FIG. 1A and 1B are schematic views illustrating the configuration of a semiconductor light emitting device according to a first embodiment of the invention.

That is, FIG. 1B is a plan view and FIG. 1A is a cross-sectional view along A-A′ line of FIG. 1B.

As shown in FIG. 1A and 1B, in a semiconductor light emitting device 101 according to the first embodiment of the invention, a laminated structure body in which an n-type semiconductor layer 1, a light emitting layer 3 and a p-type semiconductor layer 2 are laminated in this order is formed on a substrate 10 made of sapphire having a single crystal buffer layer 11 made of AlN sandwiched therebetween. A p-side electrode (second electrode) 4 and an n-side electrode (first electrode) 7 are provided on the same major surface of this laminated structure body 1s.

The p-side electrode 4 serving as a high-efficiency reflection film is provided on the p-type semiconductor layer 2. The p-type semiconductor layer 2 is partly etched away, and an n-side electrode 7 serving as the high-efficiency reflection film is provided on the exposed n-type semiconductor layer 1. The n-side electrode 7 includes at least one of silver and silver alloy.

That is, the semiconductor light emitting device 101 according to the first embodiment of the invention includes: the laminated structure body 1s having the n-type semiconductor layer 1, the p-type semiconductor layer 2 and the light emitting layer 3 provided between the n-type semiconductor layer 1 and the p-type semiconductor layer 2, having the p-type semiconductor layer and the light emitting layer 3 selectively etched and having an exposed portion of the n-type semiconductor layer 1 to a first major surface la on the p-type semiconductor layer side; the n-side electrode 7 provided on the first major surface side of the laminated structure body 1s, connected to the n-type semiconductor layer 1 and including at least one of silver and silver alloy; and the p-side electrode provided on the first major surface 1a side of the laminated structure body 1s and connected to the p-type semiconductor layer 2.

In the semiconductor light emitting device 101 according to this embodiment, an n-type GaN on the single crystal buffer layer 11 made of AlN formed by a method described later has excellent flatness and few defects, and high concentration Si doping is possible, and hence ohmic contact can be formed by silver being usually difficult to ensure excellent electric characteristics. Thus, the n-side electrode region with extremely low reflectivity in a conventional structure can be constituted by a high-efficiency reflection film, and hence the light emitted from the light emitting layer 3 can be reflected with high efficiency to be extracted outside the device. That is, the light extraction efficiency of the semiconductor light emitting device can be increased. Thus, the semiconductor light emitting device 101 can provide a semiconductor light emitting device capable of extracting the light generated in the light emitting layer outside efficiently.

As described later, the single crystal buffer layer 11 can include at least one of AlN and AlxGa1-xN (0.8≦x≦1). Thus, the flatness is excellent, the defects are few and high concentration Si doping is possible, and hence ohmic contact can be formed by silver being usually difficult to ensure excellent electric characteristics.

In the specific example shown in FIG. 1B, the n-side electrode 7 occupies a corner of the semiconductor light emitting device shaped like a square, however the shape of the n-side electrode 7 is not limited thereto.

Next, a specific example of a laminated structure of a semiconductor layer formed on the substrate 10 will be described. The semiconductor light emitting device 101 according to this example is composed of nitride semiconductor formed on the substrate 10 made of sapphire.

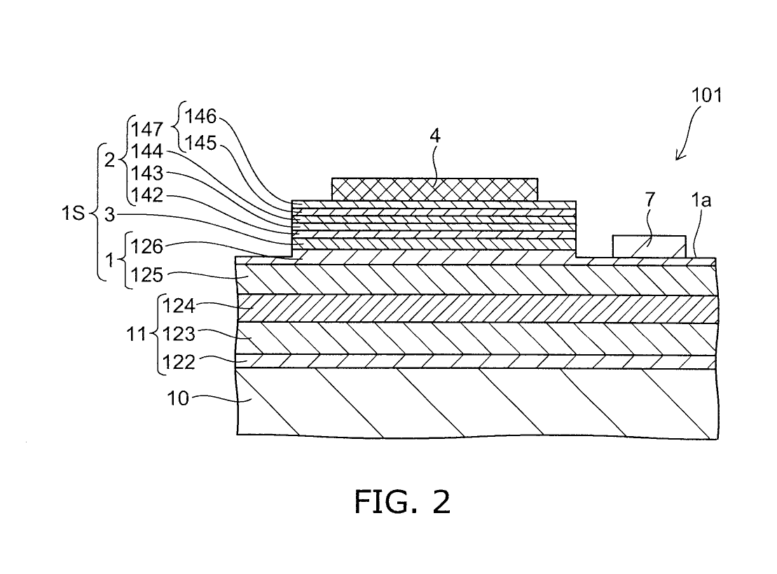

FIG. 2 is a schematic view illustrating the configuration of the semiconductor light emitting device according to the first embodiment of the invention.

As shown in FIG. 2, for example, on the substrate 10 with the surface being the sapphire c-plane, metal organic chemical vapor deposition is used to sequentially laminate a first buffer layer 122 made of single crystal AlN with high carbon concentration (with a carbon concentration of 3×10¹⁸-5×10²⁰ cm⁻³) to a thickness of 3-20 nm, a second buffer layer 123 made of single crystal AlN with high purity (with a carbon concentration of 1×10¹⁶-3×10¹⁸ cm⁻³) to 2 μm, a third buffer layer 124 made of non-doped GaN to 3 μm, a Si-doped n-type GaN contact layer 125 (with a Si concentration of 1×10¹⁸-5×10¹⁸ cm⁻³) to 4 μm, a Si-doped n-type GaN contact layer 126 (with a Si concentration of 1.1×10¹⁸-3×10²⁰ cm⁻³) to 0.2 μm, a Si-doped n-type Al_{0.10}Ga_{0.90}N cladding layer (with a Si concentration of 1×10¹⁸ cm⁻³) to 0.02 μm, a light emitting layer 3 of the multiple quantum well structure to 0.075 μm in which a Si-doped n-type Al_{0.11}Ga_{0.89}N barrier layer (with a Si concentration of 1.1-1.5×10¹⁹ cm⁻³) and a GaInN light emitting layer (with a wavelength of 380 nm) are alternately laminated three times, a final Al_{0.11}Ga_{0.89}N barrier layer of the multiple quantum well (with a Si concentration of 1.1-1.5×10¹⁹ cm⁻³) to 0.01 μm, a Si-doped n-type Al_{0.11}Ga_{0.89}N layer 142 (with a Si concentration of 0.8-1.0×10¹⁹ cm⁻³) to 0.01 μm, a non-doped Al_{0.11}Ga_{0.89}N spacer layer 143 to 0.02 μm, a Mg-doped p-type Al_{0.28}Ga_{0.72}N cladding layer 144 (with a Mg concentration of 1×10¹⁹ cm⁻³) to 0.02 μm, a Mg-doped p-type GaN contact layer 145 (with a Mg concentration of 1×10¹⁹ cm⁻³) to 0.1 μm, and a highly Mg-doped p-type GaN contact layer 146 (with a Mg concentration of 2×10²⁰ cm⁻³) to 0.02 μm.

A p-type GaN contact layer 147 has the Mg-doped p-type GaN contact layer 145 and the highly Mg-doped p-type GaN contact layer 146.

By setting the Mg concentration in the Mg-doped p-type GaN contact layer 146 to a relatively high level on the order of 1×10²⁰ cm⁻³, its ohmic contact with the p-side electrode 4 is improved. However, in the case of semiconductor light emitting diodes, as opposed to semiconductor laser diodes, the distance between the highly Mg-doped p-type GaN contact layer 146 and the light emitting layer 3 is small, causing concern about characteristics degradation due to Mg diffusion. Thus, by taking advantage of the large contact area between the p-side electrode 4 and the highly Mg-doped p-type GaN contact layer 146 and the low current density during operation, the Mg concentration in the highly Mg-doped p-type GaN contact layer 146 can be reduced to the order of 1×10¹⁹ cm⁻³ without substantially compromising electrical characteristics to prevent Mg diffusion and improve light emission characteristics.

In this specific example, the single crystal buffer layer 11 includes the first buffer layer 122 (high carbon concentration portion) made of AlN with high carbon concentration, the second buffer layer 123 made of AlN with high purity and the third buffer layer 124 made of non-doped GaN. Thus, the carbon concentration in the substrate 10 side of the aluminum nitride layer serving as the single crystal buffer layer 11 is higher than that in the light emitting layer 3 side.

The first buffer layer 122 with high carbon concentration serves to alleviate its difference in crystal form from the substrate 10, and particularly reduces screw dislocation. The thickness of the first buffer layer 122 is preferable to be from 3 nm to 20 nm inclusive.

The second buffer layer 123 with high purity has a flat surface at the atomic level. This reduces defects in the non-doped GaN buffer layer 124 grown thereon. To this end, the thickness of the second AlN buffer layer with high purity is preferably larger than 1 μm. Furthermore, to avoid warpage due to strain, the thickness is preferably 4 μm or less.

The second buffer layer 123 with high purity is not limited to AlN, but can be AlₓGa₁₋ₓN (0.8≦x≦1) to compensate for wafer warpage.

The third buffer layer 124 serves to reduce defects by three-dimensional island growth on the second buffer layer 123 with high purity. The average thickness of the third buffer layer 124 needs to be 2 μm or more to achieve a flat growth surface. From the viewpoint of reproducibility and warpage reduction, it is suitable that the total thickness of the third buffer layer 124 is 4 to 10 μm.

Use of the single crystal buffer layers 11 having the configuration like this successfully reduces defects to approximately 1/10 of those in the conventional low-temperature grown AlN buffer layer. This technique enables high concentration Si doping to the Si-doped n-type GaN contact layer 126 and fabrication of a semiconductor light emitting device with high efficiency despite its capability of emission in the ultraviolet band. Moreover, by reducing crystal defects in the single crystal buffer layer 11, light absorption in the single crystal buffer layer 11 can be suppressed. According to this embodiment, by providing the n-side electrode 7 of the high-efficiency reflection film, the light emitted from the light emitting layer 3 can be reflected with high efficiency to be extracted outside the device.

In the above, the third buffer layer can be omitted. Also in this case, the flatness is excellent, the defects are few and high concentration Si doping is possible.

Next, one example of a forming method of an electrode on a semiconductor layer will be described.

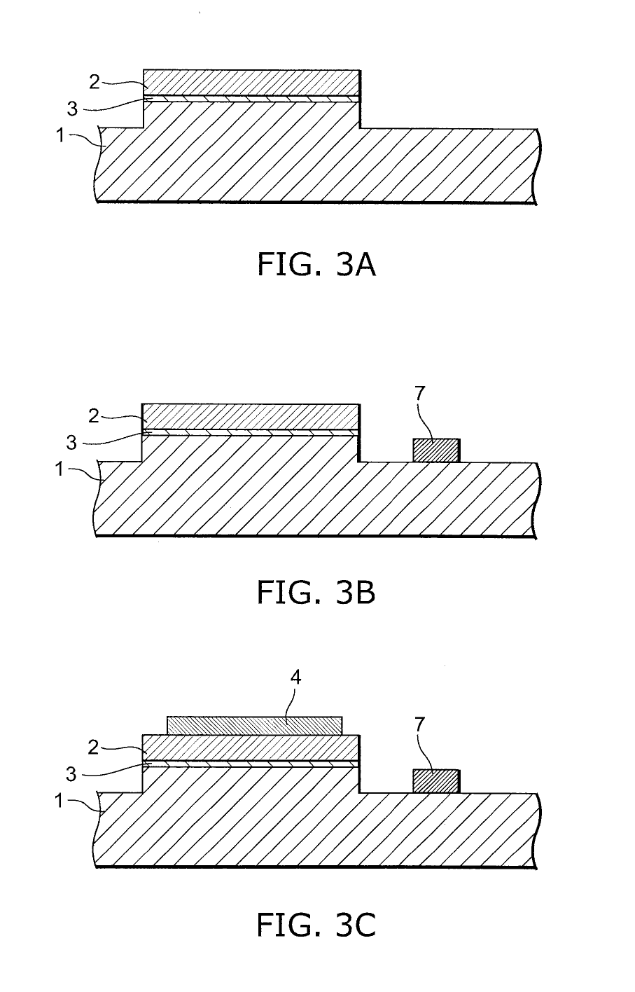

FIGS. 3A to 3C are schematic sequential process cross-sectional views illustrating part of a method for manufacturing the semiconductor light emitting device according to the first embodiment of the invention.

That is, the figures illustrate a part of manufacturing processes of the semiconductor light emitting device 101 illustrated in FIGS. 1A and 1B.

First, as shown in FIG. 3A, part of the p-type semiconductor layer 2 and the light emitting layer 3 are removed by dry etching using a mask so that the n-type contact layer is exposed to the surface in a region of the p-type semiconductor layer 2. Then, a part of the n-type semiconductor layer 1 is exposed. Specifically, a part of the Si-doped n-type GaN contact layer 126 shown in FIG. 2 is exposed.

Next, as shown in FIG. 3B, the n-side electrode 7 having ohmic characteristics and high-efficiency reflection characteristics is formed. For example, a lift-off resist pattern is formed on the exposed n-type contact layer, the n-side electrode 7 illustratively made of Ag/Pd serving as an ohmic contact region is formed with a thickness of 200 nm using a vacuum deposition system, and sintered in a nitrogen atmosphere at 650° C.

Next, as shown in FIG. 3C, to form the p-side electrode 4, a lift-off resist pattern is formed on the p-type contact layer, Ag/Pd is formed with a thickness of 200 nm using a vacuum deposition system, and sintered in a nitrogen atmosphere at 350° C. after the lift-off.

Then, discrete LED devices are produced by cleavage or diamond blade cutting.

Thus, the semiconductor light emitting device 101 is manufactured.

As illustrated in FIG. 1, in the region of the n-side electrode 7, the current injected from outside the semiconductor light emitting device 101 into the p-side electrode 4 and flowing through the semiconductor layer to the n-side electrode 7 is extracted outside the semiconductor light emitting device. Thus, the region of the n-side electrode 7 needs to be designed with a large area in relation to wire bonding and bump formation for contact between the semiconductor light emitting device 101 and the external terminal. The size of the n-side electrode region 7 is e.g. approximately 120 μm to 150 μm.

As described above, the n-side electrode 7 is formed by a high-efficiency reflection film including at least one of silver and a silver alloy, and hence a reflection region of the major surface la of the laminated structure body is of the semiconductor layer having the electrode formed thereon can be broadened largely. Thus, when flip chip mount is performed, the most part of emitted light reflecting repeatedly in the semiconductor layer can be reflected to the side of the substrate 10, and hence the light extraction efficiency can be improved.

The n-side electrode 7 includes at least one of silver and a silver alloy. The reflection efficiency of a single-layer metal film for the visible band tends to decrease in the ultraviolet band of 400 nm or less as the wavelength becomes shorter. However, silver has high reflection efficiency also for light in the ultraviolet band from 370 nm to 400 nm inclusive. Hence, in the case where the semiconductor light emitting device 101 according to this embodiment is suitable for ultraviolet emission with the n-side electrode 7 made of a silver alloy, it is preferable to increase the component ratio of silver in the n-side electrode 7 on the semiconductor interface side. The thickness of the n-side electrode 7 is preferably 100 nm or more to ensure sufficient light reflection efficiency. As with silver, aluminum has high reflection efficiency also for light in the ultraviolet band from 370 nm to 400 nm inclusive, hence it is preferable to increase the component ratio of aluminum in the n-side electrode 7 on the semiconductor interface side. Conventionally, ohmic contact has been difficult to be formed stably between an n-type contact layer and aluminum, however, in the semiconductor light emitting device 101 according to this embodiment, high concentration Si doping to the Si doped n-type GaN contact layer 126 is possible, and thus it has become possible to achieve ohmic contact with aluminum and low contact resistance.

The p-side electrode 4 can also include at least one of silver and a silver alloy, and hence, a reflection region of the major surface is of the laminated structure body is of the semiconductor layer having the electrode formed thereon can be broadened largely. Thus, when flip chip mount is performed, the most part of emitted light reflecting repeatedly in the semiconductor layer can be reflected to the side of the substrate 10, and hence the light extraction efficiency can be improved.

Also in this case, in the case where the semiconductor light emitting device 101 according to this embodiment is suitable for ultraviolet emission with the p-side electrode 4 made of a silver alloy, it is preferable to increase the component ratio of silver in the p-side electrode 4 on the semiconductor interface side. The thickness of the p-side electrode 4 is preferably 100 nm or more to ensure sufficient light reflection efficiency.

The p-side electrode 4 is formed from a Ag/Pt laminated film and thereafter sintered, thereby very little Pt can be diffused into the interface between the high concentration Mg doped p-type GaN contact layer 146 and Ag. Thus, adhesiveness of Ag is improved and a contact resistance can be reduced without reducing the high-efficiency reflection characteristics specific to Ag, and hence both of high-efficiency reflection characteristics and low operation voltage characteristics required for the p-side electrode 4 can be highly compatible. That is, in the case where Pt is diffused into the above interface, the operation voltage at 20 mA can be reduced by 0.3 V while outputting substantially the same optical output, compared with the case where a Ag single layer is served as the p-side electrode 4 on the same heat treatment condition as the condition described with regard to FIG. 3.

Ag is soluble with Pt, and Ag is soluble with Pd, therefore by blending Pt or Pd with Ag, migration of Ag can be suppressed. Particularly, since Pd and Ag are complete solubility in the solid state, the migration of Ag can be effectively suppressed. By adopting these combinations for the p-side electrode 4 and the n-side electrode 7, high reliability can be obtained even if a high current is injected.

In the case where the p-side electrode 4 and the n-side electrode 7 include at least one of silver and a silver alloy, as the distance between the p-side electrode 4 and the n-side electrode 7 increases, the risk of insulation failure and breakdown voltage failure due to migration of silver or its alloy decreases. As the p-side electrode 4 which faces the n-side electrode 7 around the center of a device is formed nearer to the end of the p-type contact layer as long as process conditions such as exposure accuracy are permissible, the light extraction efficiency is improved. With regard to the current path from the p-side electrode 4 to the n-side electrode 7, the current tends to concentrate on the region with the shortest distance between the p-side electrode and the n-side electrode 7. Hence, to alleviate electric field concentration, the above region with the shortest distance is preferably designed to be as long as possible of the region in which the p-side electrode faces the n-side electrode 7. Furthermore, in plan view, as the length of the region in which the p-side electrode 4 faces the n-side electrode 7 increases, the number of current paths from the p-side electrode 4 to the n-side electrode 7 increases, which results in alleviating electric field concentration and preventing degradation of the p-side electrode 4 and the n-side electrode 7. With these effects into consideration, it is possible to freely determine the area and configuration of the p-side electrode and the n-side electrode 7 and the distance between the p-side electrode and the n-side electrode 7.

In the semiconductor light emitting device 101 according to this embodiment, by making the n-side electrode 7 of the high-efficiency reflection film, the most part of the major surface la of the laminated structure body is of the semiconductor layer having the electrode formed thereon can be reflective, the most part of emitted light reflecting repeatedly in the semiconductor layer can be reflected to the side of the substrate 10, and hence the light extraction efficiency can be expected.

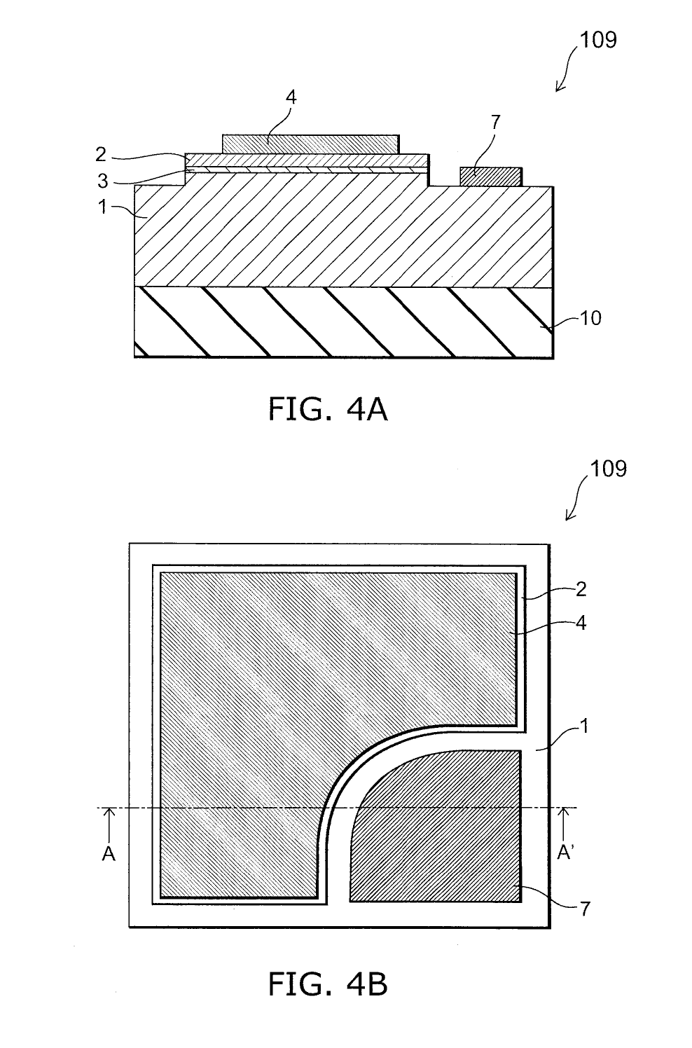

FIGS. 4A and 4B are schematic views showing the structure of a semiconductor light emitting device of a comparative example.

That is, FIG. 4B is a plan view, and FIG. 4A is a cross-sectional view along A-A′ line of FIG. 4B.

As shown in FIGS. 4A and 4B, in the semiconductor light emitting device 109 of the comparative example, the n-side electrode 7 is composed of Ti/Al/Ni/Au. Except the above, the comparative example is the same as the semiconductor light emitting device 101 according to this embodiment and not described.

That is, for example, a lift-off resist pattern is formed on the semiconductor layer, Ti/Al/Ni/Au serving as the n-side electrode 7 is formed with a thickness of 400 nm on the n-type contact layer using a vacuum deposition system, and sintered in a nitrogen atmosphere at 650° C. after the lift-off. A similar lift-off pattern resist is formed on the semiconductor layer, Ag/Pt serving as the p-side electrode 4 is formed with a thickness of 200 nm on the p-type GaN contact layer 137 using a vacuum deposition system, and sintered in a nitrogen atmosphere at 350° C. after the lift-off.

In semiconductor light emitting device 109 of the comparative example, the n-side electrode 7 is formed from a metal having a reflectivity of about 10% or less. Therefore, the light extraction efficiency of the light emitted from the light emitting layer 3 is low.

In contrast, in the semiconductor light emitting device according to this embodiment, the n-side electrode 7 is formed from a high-efficiency reflection film including at least one of silver and a silver alloy, and the most of the major surface of the laminated structure body having the electrode formed thereon is reflective, and thus the light extraction efficiency can be improved.

In the semiconductor light emitting device 101 according to this embodiment, use of a crystal on the single crystal buffer layer 11 enables high concentration Si to be doped into the Si doped n-type GaN contact layer 126 and the contact resistance to the n-side electrode 7 to be reduced drastically. Therefore, the n-side electrode 7 becomes easy to be based on silver and a silver alloy serving as the high-efficiency reflection film which has poor ohmic contact and a high contact resistance conventionally. Moreover, reduction of crystal defects enables high light emission efficiency to be achieved even if in shorter wavelength band than 400 nm with usually decreasing efficiency.

When an amorphous or polycrystalline AlN layer is provided as a buffer layer in order to alleviate the difference in crystal form on the substrate 10 made of sapphire, buffer layer itself absorbs light and hence the light extraction efficiency of a light emitting device decreases.

In contrast, on the substrate 10 made of sapphire is formed the n-type semiconductor layer 1, the light emitting layer 3 and the n-type semiconductor layer 2 through the first buffer layer 122 made of AlN with high carbon concentration and the second buffer layer 123 made of single crystal AlN with high purity, and hence the first buffer layer 122 and the second buffer layer 123 are difficult to absorb light and crystal defects are drastically reduced, thus absorber in the crystal can be drastically reduced. In this case, it becomes possible for the emitted light to be repeatedly reflected many times within the crystal, and the light extraction efficiency in a lateral direction can be raised and the light can be efficiently reflected to the n-side electrode 7 serving as high-efficiency reflection region. These effects make it possible to achieve improvement of light emission intensity, high through put and low cost.

It is noted that in the semiconductor light emitting device 101 according to this embodiment, the p-side electrode 4 is illustratively based on a transparent electrode such as ITO (Indium Tin Oxide) and the light may be extracted from the side of the first major surface la of the semiconductor light emitting device 101.

That is, the p-side electrode 4 enables the light emitted from the light emitting layer 3 to pass through.

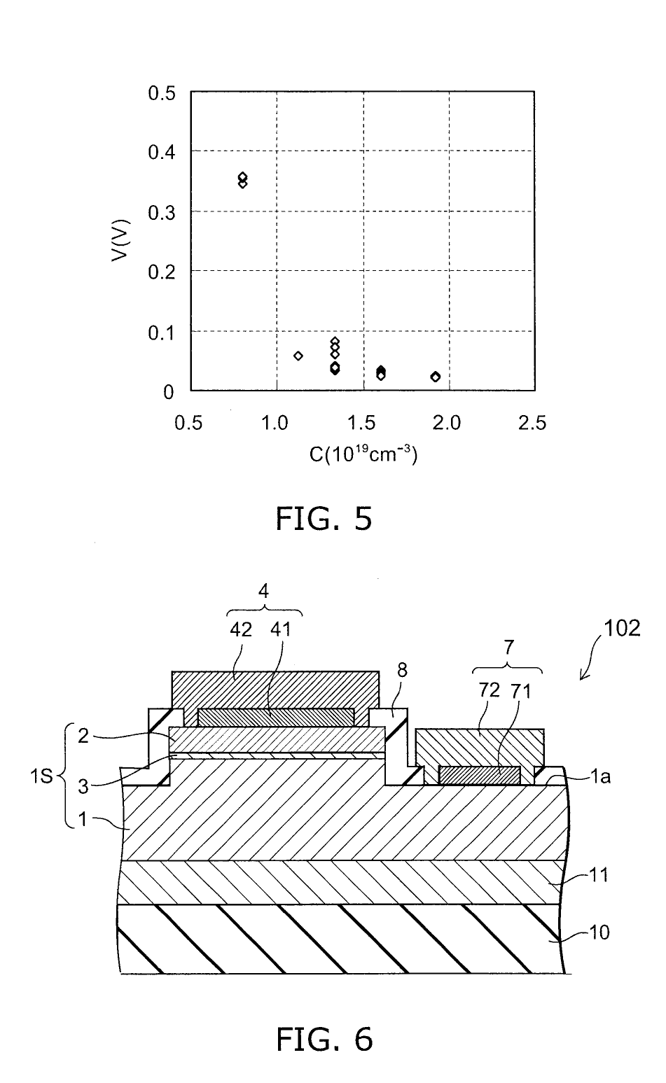

FIG. 5 is a graph view illustrating the characteristics of the semiconductor light emitting device according to the first embodiment of the invention.

That is, the figure illustrates an experimental evaluation result of electromotive force V between the n-side electrodes 7 on the wafer before a process for a device process while varying the Si concentration C in the Si doped n-type contact layer 126, and a horizontal axis represents the Si concentration C and a vertical axis represents the electromotive force V between the n-side electrodes 7. The electromotive force V is a value when a current of 1 mA is passed through the semiconductor light emitting device 101.

As shown in FIG. 5, as the Si concentration C in the Si doped n-type contact layer 126 increases, the electromotive force V decreased, and when the Si concentration C is 1.1×10¹⁹ cm⁻³ or more, this decrease is apparent. The electromotive force at a low current is small if ohmic contact with the n-side electrode 7 is well, and is large if ohmic contact is bad. Under well ohmic contact, even if the contact resistance is rather higher, the resistance can be reduced by designing the n-side electrode 7 so as to broaden the effective electrode area, and thereby the operation voltage can be reduced.

Thus, the Si concentration C in the Si doped n-type contact layer 126 is preferably 1.1×10¹⁹ cm⁻³ or more.

A Si doped GaN layer having Si concentration C of 3.0×10¹⁹ cm⁻³ was formed to have a slightly rough surface. From this, it is considered that when the Si concentration is higher than this, crystal quality is extremely deteriorated. Therefore, it is preferable that the Si concentration doped into the Si doped n-type contact layer 126 is 3.0×10¹⁹ cm⁻³ or less.

From the result illustrated in FIG. 5 and empirical rules obtained from a lot of experiments, it is preferable that the Si concentration C in the Si doped n-type contact layer 126 is not less than 1.1×10¹⁹ cm⁻³ and not more than 3.0×10¹⁹ cm⁻³.

The semiconductor light emitting device 101 according to this embodiment has at least the n-type semiconductor layer, the p-type semiconductor layer and the semiconductor layer including the light emitting layer 3 sandwiched therebetween, and the material used for the semiconductor layer is not particularly limited, but for example, a gallium nitride based compound semiconductor such as AlₓGa_{1-x-y}In_{y}N (x≧0, y≧0, x+y≦1) or the like is used. The method for forming these semiconductor layers is not particularly limited, but it is possible to use publicly known techniques such as metal organic chemical vapor deposition and molecular beam epitaxy.

The material of the substrate 10 is also not particularly limited, but it is possible to use general substrate materials such as sapphire, SiC, GaN, GaAs, and Si. The substrate 10 may be finally removed.

Particularly, use of a sapphire substrate for the substrate makes it easy to achieve a crystal with excellent characteristics. That is, the semiconductor light emitting device 101 according to this embodiment can further comprise the substrate provided on a second major surface side of the laminated structure body is facing the first major surface and made of sapphire.

The laminated structure body can further include a single crystal buffer layer provided between the substrate 10 and the n-type semiconductor layer 1, and including at least one of AlN and AlₓGa₁₋ₓN (0.8≦x≦1).

### Second Embodiment

FIG. 6 is a schematic cross-sectional view illustrating the structure of a semiconductor light emitting device according to a second embodiment of the invention.

As shown in FIG. 6, in the semiconductor light emitting device 102 according to the second embodiment of the invention, the p-side electrode 4 has a first metal film 41 and a second metal film 42. The first metal film 41 is provided between the second metal film 42 and the p-type semiconductor layer 2. The n-side electrode 7 has a third metal film 71 and a fourth metal film 72. The third metal film 71 is provided between the fourth metal film 72 and the n-type semiconductor layer 1. With regard to other than the above, the semiconductor light emitting device 102 can be the same as the semiconductor light emitting device 101 and not described.

The first metal film 41 and the third metal film 71 are the high-efficiency reflection film and can be based on at least one of silver and a silver alloy.

The first metal film 41 and the third metal film 71 can be formed simultaneously as described later. The second metal film 42 and the fourth metal film 72 can be based on any material.

In the semiconductor light emitting device 102, the p-side electrode 4 has the first metal film 41 provided on the p-type semiconductor layer 2 and the second metal film 42 provided so as to cover the first metal film 41, and the n-side electrode 7 has the third metal film 71 provided on the n-type semiconductor layer 1 and made of the same material as the first metal film 41 and the fourth metal film 72 provided so as to cover the third metal film 71.

That is, in the semiconductor light emitting device 102 according to this embodiment, high-efficiency reflection films (the first metal film 41 and the third metal film 71) serving as part of the p-side electrode 4 and the n-side electrode 7 are formed simultaneously, and their surroundings are covered with metal films (the second metal film 42 and the fourth metal film 72).

In the semiconductor light emitting device 102 according to this embodiment, the first metal film 41 is covered with the second metal film 42 and the third metal film 71 is covered with the fourth metal film 72, and hence the first metal film 41 and the third metal film 71 are isolated from ambient air and a dielectric film 8. Thus, the first metal film 41 and the third metal film 71 are less likely to be exposed to moisture and impurity ions, and migration, oxidation, and sulfidation of silver can be prevented.

Furthermore, the second metal film 42 and the fourth metal film 72 are placed immediately beside the edge of the first metal film 41 and the edge of the third metal film 71 facing the p-side electrode 4 and the n-side electrode 7, respectively, allowing a current path to be formed immediately beside the first metal film 41 and the third metal film 71. This alleviates current concentration on the first metal film 41 and the third metal film 71.

Simultaneously, a region sandwiched between the p-type semiconductor layer 2 and the second metal film 42 and a region sandwiched between the n-type semiconductor layer 1 and the fourth metal film 72 occur near the edge of the dielectric film 8 facing the p-side electrode 4 and the n-side electrode 7. Hence, a weak electric field is applied across the dielectric film 8 between the n-type semiconductor layer 1 and the fourth metal layer 72. This results in a structure in which the electric field is gradually weakened from the first metal film 41 to the dielectric film 8 and from the third metal film 71 to the dielectric film 8. Hence, electric field concentration in these regions can be alleviated.

Furthermore, the manufacturing process requires no special ingenuity for the above structure, but the device can be formed in the same process and number of steps as in conventional techniques. These effects allow a semiconductor light emitting device to achieve reduction of leakage current, improvement in insulation characteristics, improvement in breakdown voltage characteristics, improvement in emission intensity, increase of lifetime, high throughput, and low cost.

That is, in the semiconductor device 102 according to this embodiment, a semiconductor light emitting device can be provided, extracting the light generated in the light emitting layer outside efficiently and allowing reduction of leakage current, improvement in insulation characteristics, improvement in breakdown voltage characteristics, improvement in emission intensity, increase of lifetime, high throughput, and low cost.

In the semiconductor device 102 according to this embodiment, it is preferable to use platinum (Pt) and rhodium (Rh) with high resistivity to environment and relatively high reflectivity for the side of contacting with the p-type contact layer in the second metal film 42 and for the side of contacting with the n-type contact layer in the fourth metal film 72. Thus, the second metal film 42 and the fourth metal film 72 can function as a protect film of the first metal film 41 and the third metal film 71 and a reflection film to the emitted light, respectively.

A long length of the second metal film 42 and the fourth metal film 72 extending on the dielectric film 8 is favorable to realizing a structure for alleviating electric field through the dielectric film 8, but increases danger of short-circuiting the p-side electrode 4 to the n-side electrode 7. On the other hand, if the length is short, there is reduced danger of short-circuiting the p-side electrode 4 to the n-side electrode 7.

In the semiconductor light emitting device 102, a pad made of Au can be also formed with a thickness of 2000 nm to cover at least part of the respective regions provided with Pt/Au, that is, the second metal film 42 and the fourth metal film 72. This enhances bondability, and improvement in heat dissipation of the semiconductor light emitting device 102 can be also expected. This pad can also be used as a gold bump, or an AuSn bump can be formed instead of Au.

In the case of separately providing a pad to enhance bondability for wire bonding, enhance die shear strength during gold bump formation by a ball bonder, and enable flip-chip mounting, the thickness of the pad is not particularly limited, but can be selected illustratively in the range of 100 to 10000 nm.

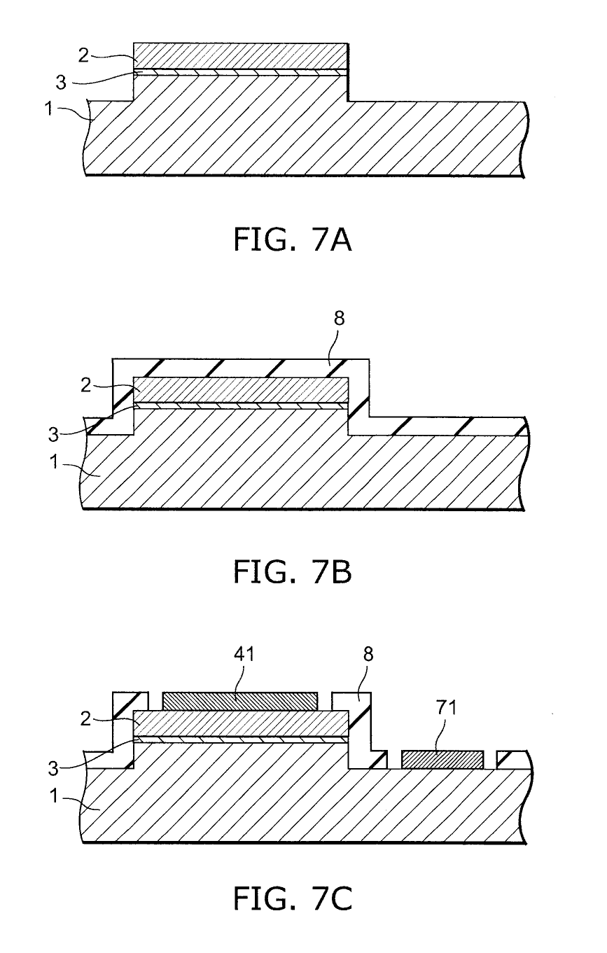

FIGS. 7A to 7C are schematic sequential process cross-sectional views illustrating part of a method for manufacturing the semiconductor light emitting device according to the second embodiment of the invention.

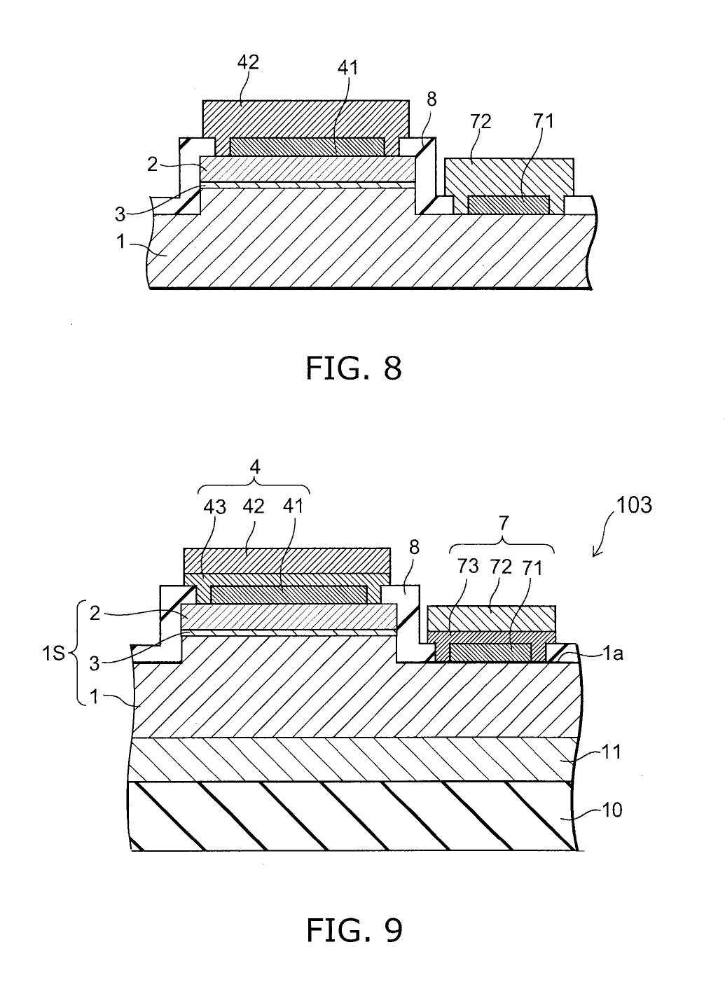

FIG. 8 is a schematic sequential process cross-sectional view following FIGS. 7A to 7C.

With regard to forming the n-type semiconductor 1, the light emitting layer 3 and the p-type semiconductor layer 2, the same method as described with regard to FIG. 2 can be used and not described.

First, as shown in FIG. 7A, part of the p-type semiconductor layer 2 and the light emitting layer 3 are removed by dry etching using a mask so that the n-type contact layer is exposed to the surface in a partial region of the p-type semiconductor layer 2.

Next, as shown in FIG. 7B, for example, a SiO₂ serving as the dielectric film 8 is formed with a thickness of 400 nm on the semiconductor using a thermal CVD system.

Next, as shown in FIG. 7C, the p-side electrode 4 and the n-side electrode 7 having ohmic characteristics and high-efficiency reflection characteristics are formed simultaneously.

That is, a lift-off resist pattern is formed on the semiconductor layer, and part of the exposed SiO₂ film on the p-type contact layer and the n-type contact layer is removed by ammonium fluoride treatment. At this time, ammonium fluoride treatment time is adjusted so that the p-type contact layer and the n-type contact layer are exposed between the first metal film 41 and the SiO₂ film serving as the dielectric film 8, and between the third metal film 71 and the SiO₂ film serving as the dielectric film 8, respectively. As a specific example, when the etching rate is 400 nm/min, the sum of time for removing the SiO₂ film in the region for forming Ag/Pt and time for over etching to expose the p-type contact layer and the n-type contact layer located immediately beside the above region by 1 μm width is about 3 minutes.

In the region where the SiO₂ film is removed, the first metal film 41 and the third metal film 71 illustratively made of Ag/Pt are formed with a thickness of 200 nm using a vacuum deposition system, and sintered in a nitrogen atmosphere at 650° C. after the lift-off.

Next, as shown in FIG. 8, a lift-off resist pattern is formed on the semiconductor layer, and the second metal film 42 and the fourth metal film 72 illustratively made of Pt/Au are formed with a thickness of 500 nm to form the p-side electrode 4 and the n-side electrode 7 to cover entirely the region having Ag/Pt formed, entirely the p-type contact layer and the n-type contact layer exposed to a surface immediately beside the Ag/Pt and part of the SiO₂ film.

In the above, before the first metal film 41 and the third metal film 71 which are ohmic metal are formed, the dielectric film 8 is formed on the semiconductor layer, and hence contamination adhered to the interface between the electrode and the semiconductor layer in the electrode formation process can be drastically reduced. Thus, reliability, yield, electrical characteristics and optical characteristics can be improved.

The second metal film 42 and the fourth metal film 72 made of a metal not containing silver, and are in electrical contact with the first metal film 41 and the third metal film 71, respectively. The material of the second metal film 42 and the fourth metal film 72 are not particularly limited, but they can be a single-layer or multilayer metal film, a metal alloy layer, a single-layer or multilayer conductive oxide film, or any combination thereof. Film thicknesses of the second metal film 42 and the fourth metal film 72 are not particularly limited, but can be selected illustratively in the range of 100 to 10000 nm.

With regard to the electrical characteristics of the junction between the second metal film 42 and the p-type contact layer 2, which is the top layer of the p-type semiconductor layer 2, this junction preferably has worse ohmic contact and a higher contact resistance than the junction between the first metal film 41 and the p-type contact layer. This facilitates efficiently injecting a current into the light emitting layer 3 located directly below the first metal film 41 and allows the light emitted from directly below the first metal film 41 to be efficiently reflected toward the substrate. Hence, the light extraction efficiency can be increased.

The second metal film 42 covers the first metal film 41, the p-type contact layer exposed between the first metal film 41 and the dielectric film 8, and part of the dielectric film 8. Similarly, the fourth metal film 72 covers the third metal film 71, the n-type contact layer exposed between the third metal film 71 and the dielectric film 8, and part of the dielectric film 8. In particular, it is preferable that the portion of the dielectric film 8 facing the p-side electrode 4 and the n-side electrode 7 is entirely covered. In view of the pattern alignment accuracy during the manufacturing process, and the area of the first metal film 41 and the third metal film 71 serving as a reflection film, the second metal film 42 and the fourth metal film 72 preferably extends in the range from 0.5 μm to 10μm.

As described above, the first metal film 41 and the third metal film 71 can be formed simultaneously, and hence the manufacturing process is simplified and favorable.

### Third Embodiment

Next, a third embodiment of the invention will be described.

FIG. 9 is a schematic cross-sectional view illustrating the structure of a semiconductor light emitting device according to the third embodiment of the invention.

As shown in FIG. 9, in the semiconductor light emitting device 103 according to the third embodiment of the invention, a fifth metal film 43 and a sixth metal film 73 are provided between the first metal film 41 and the second metal film 42, and between the third metal film 71 and the fourth metal film 72, respectively. Except the above, the semiconductor light emitting device 103 can be the same as the semiconductor light emitting device 102 and not described.

The fifth metal film 43 can be based on material which does not react with silver or not actively diffuse into silver in order to prevent the material contained in the second metal film 42 from diffusing into the first metal film 41 or the second metal film 42 from reacting with the first metal film 41. The fifth metal film 43 can be electrically connected to the first metal film 41 and the second metal film 42.

The sixth metal film 73 can be based on material which does not react with silver or not actively diffuse into silver in order to prevent the material contained in the fourth metal film 72 from diffusing into the third metal film 71 or the fourth metal film 72 from reacting with the third metal film 71. The sixth metal film 73 can be electrically connected to the third metal film 71 and the fourth metal film 72.

This can suppress the material contained in the second metal film 42 from diffusing into the first metal film 41 or the second metal film 42 from reacting with the first metal film 41, and the material contained in the fourth metal film 72 from diffusing into the third metal film 71 or the fourth metal film 72 from reacting with the third metal film 71, and a semiconductor light emitting device with high reliability is achieved.

The fifth metal film 43 and the sixth metal film 73 can be a single-layer or laminated film usable as a diffusion prevention layer made of a high melting point metal such as vanadium (V), chromium (Cr), iron (Fe), cobalt (Co), nickel (Ni), niobium (Nb), molybdenum (Mo), ruthenium (Ru), rhodium (Rh), tantalum (Ta), tungsten (W), rhenium (Re), osmium (Os), iridium (Ir), and platinum (Pt).

To ensure that no problem occurs due to some diffusion into the fifth metal film 43, it is more preferable to use a metal having a high work function and being likely to form ohmic contact with the p-GaN contact layer, such as iron (Fe), cobalt (Co), nickel (Ni), rhodium (Rh), tungsten (W), rhenium (Re), osmium (Os), iridium (Ir), and platinum (Pt).

To ensure that no problem occurs due to some diffusion into the sixth metal film 73, it is more preferable to use a metal having a low work function such as niobium (Nb), molybdenum (Mo) and tantalum (Ta).

In the case of a single-layer film, the thicknesses of the fifth metal film 43 and the sixth metal film 73 are preferably in the range of 5 to 200 nm to maintain the film condition. In the case of a laminated film, the thicknesses are not particularly limited, but can be selected illustratively in the range of 10 to 10000 nm.

That is, in the semiconductor device 103 according to this embodiment, a semiconductor light emitting device can be provided, extracting the light generated in the light emitting layer outside efficiently and allowing reduction of leakage current, improvement in insulation characteristics, improvement in breakdown voltage characteristics, improvement in emission intensity, increase of lifetime, high throughput, low cost, and high reliability.

### Fourth Embodiment

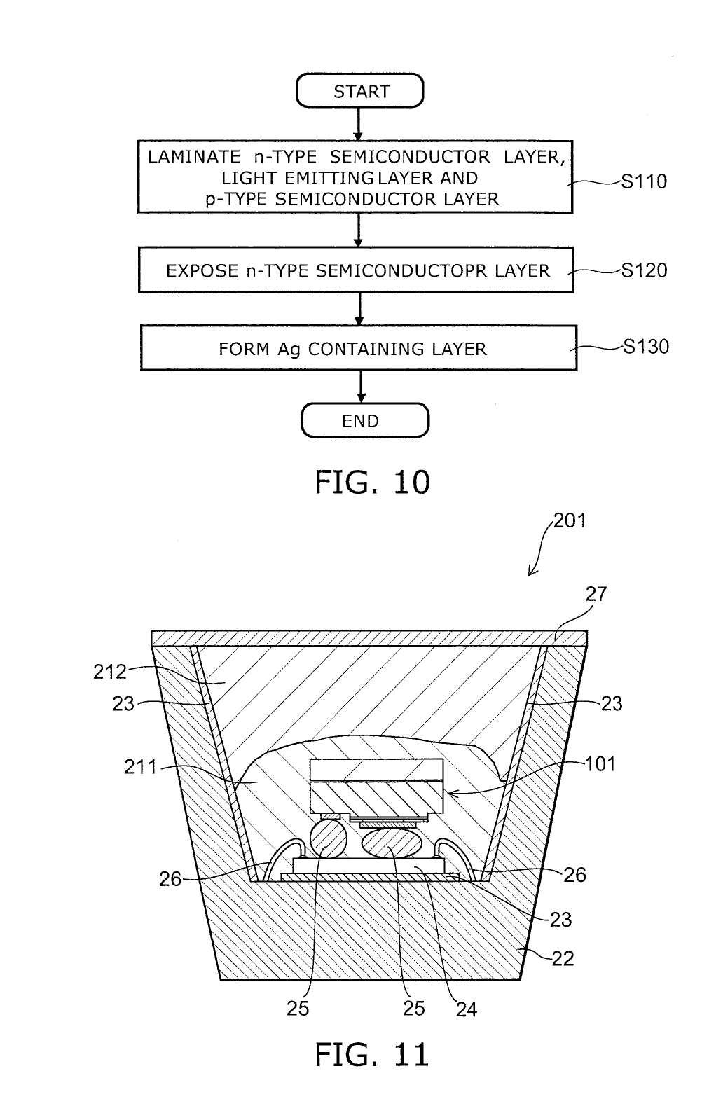

FIG. 10 is a flow chart illustrating a method for manufacturing a semiconductor light emitting device according to a fourth embodiment of the invention.

As shown in FIG. 10, in the method for manufacturing the semiconductor light emitting device according to the fourth embodiment of the invention, first, the n-type semiconductor layer 1, the light emitting layer 3 and the p-type semiconductor layer 2 are laminated on the substrate(step S110). This can be illustratively based on the method described with reference to FIG. 2

Moreover, parts of the p-type semiconductor layer 2 and the light emitting layer 3 are removed to expose a part of the n-type semiconductor layer 1 (step S120). This can be illustratively based on the method described with reference to FIG. 2 and FIG. 5.

Furthermore, a silver containing film including at least one of silver and a silver alloy is formed on the exposed n-type semiconductor layer 1 and the p-type semiconductor layer 2 (step S130). This silver containing film is the first metal film 41 and the third metal film 71 described above, capable to be formed simultaneously. Moreover, here, the material described with regard to the material which can be used for the first metal film 41 and the third metal film 71 can be applied to the silver containing film.

Thus, the first metal film 41 and the third metal film 71 can be formed simultaneously, and hence the manufacturing process is simplified, and a semiconductor light emitting device extracting the light generated in the light emitting layer outside effectively can be manufactured effectively.

### Fifth Embodiment

FIG. 11 is a schematic view illustrating the configuration of a semiconductor light emitting apparatus according to a fifth embodiment of the invention.

The semiconductor light emitting apparatus 201 according to the fifth embodiment of the invention is a white LED in which at least any of the semiconductor light emitting devices 101 to 103 according to the first to third embodiment is combined with phosphors. That is, the semiconductor light emitting apparatus 201 according to this embodiment comprises any of the above semiconductor light emitting devices, and phosphors absorbing the light emitted from the semiconductor light emitting device and emitting light having a different wave length from the light.

It is noted that in the following, by way of example, a combination of the above semiconductor light emitting device 101 and the phosphors is described.

That is, as illustrated in FIG. 11, in the semiconductor light emitting apparatus 201 according to this embodiment, a reflection film 23 is provided on the inner surface of a package 22 made of ceramic or the like, and the reflection film 23 is separately provided on the inner side surface and the bottom surface of the package 22. The reflection film 23 is illustratively made of aluminum. The semiconductor light emitting device shown in FIG. 1 is placed via a submount 24 on the reflection film 23 provided at the bottom of the package 22.

Gold bumps 25 are formed by a ball bonder on the semiconductor light emitting device and fixed to the submount 24. Alternatively, the semiconductor light emitting device can be directly fixed to the submount 24 without using gold bumps 25.

To fix the semiconductor light emitting device 101, the submount 24, and the reflection film 23, bonding with adhesive and soldering can be used.

The surface of the submount 24 on the semiconductor light emitting device 101 side is provided with electrodes which are patterned so that the p-side electrode 4 and the n-side electrode 7 of the semiconductor light emitting device 101 are insulated from each other. The electrodes are connected through bonding wires 26 to electrodes, not shown, provided on the package 22. This connection is formed between the reflection film 23 on the inner side surface and the reflection film 23 on the bottom surface.

Furthermore, a first phosphor layer 211 containing red phosphor is formed so as to cover the semiconductor light emitting device 101 and the bonding wires 26. On the first phosphor layer 211 is formed a second phosphor layer 212 containing blue, green, or yellow phosphor. A lid 27 made of a silicone resin is provided on this phosphor layer.

The first phosphor layer 211 contains a resin and a red phosphor dispersed in the resin.

The red phosphor can be based on a matrix such as Y₂O₃, YVO₄, and Y₂(P,V)O₄, and contains therein trivalent Eu (Eu³⁺) as an activator. That is, Y₂O₃:Eu³⁺, YVO₄:Eu³⁺ and the like can be used as a red phosphor. The concentration of Eu³⁺ can be 1% to 10% in terms of molarity. Besides Y₂O₃ and YVO₄, the matrix of the red phosphor can be LaOS or Y₂(P,V)O₄. Moreover, besides Eu³⁺, it is also possible to use Mn⁴⁺ and the like. In particular, addition of a small amount of Bi in combination with trivalent Eu to the YVO₄ matrix increases absorption at 380 nm, and hence the light emission efficiency can be further increased. The resin can be a silicone resin and the like.

The second phosphor layer 212 contains a resin and at least any of a blue, green, and yellow phosphor dispersed in the resin. For example, it is possible to use a combination of blue phosphor and green phosphor, a phosphor combining blue phosphor with yellow phosphor, and a phosphor combining blue phosphor, green phosphor, and yellow phosphor.

The blue phosphor can be illustratively (Sr,Ca)₁₀(PO₄)₆Cl₂:Eu²⁺ and BaMg₂Al₁₆O₂₇:Eu²⁺ and the like.

The green phosphor can be illustratively Y₂SiO₅:Ce³⁺,Tb³⁺ with trivalent Tb acting as an emission center. In this case, energy transfer from the Ce ion to the Tb ion enhances excitation efficiency. Alternatively, the green phosphor can be illustratively Sr₄Al₁₄O₂₅:Eu²⁺ and the like.

The yellow phosphor can be illustratively Y₃Al₅:Ce³⁺ and the like.

The resin can be a silicone resin and the like.

In particular, trivalent Tb exhibits sharp emission around 550 nm where the visibility is maximized. Hence, its combination with the red emission of trivalent Eu significantly enhances light emission efficiency.

In the semiconductor light emitting apparatus 201 according to this embodiment, the 380-nm ultraviolet light generated from the semiconductor light emitting device 101 according to the first embodiment is emitted toward the substrate 10 of the semiconductor light emitting device 101. In combination with reflection at the reflection film 23, the above phosphors contained in the phosphor layers can be efficiently excited.

For example, the above phosphor contained in the first phosphor layer 211 with trivalent Eu acting as an emission center converts the above light into light with a narrow wavelength distribution around 620 nm, and red visible light can be efficiently obtained.

Furthermore, the blue, green, and yellow phosphor contained in the second phosphor layer 212 are efficiently excited, and blue, green, and yellow visible light can be efficiently obtained.

As a color mixture of these, white light and light of various other colors can be obtained with high efficiency and good color rendition.

Next, a method for manufacturing a semiconductor light emitting apparatus 201 according to this embodiment is described.

The process for fabricating the semiconductor light emitting device 101 can be based on the method described previously, and hence in the following, processes after completion of the semiconductor light emitting device 101 will be described.

First, a metal film to serve as a reflection film 23 is formed on the inner surface of the package 22 illustratively by sputtering, and this metal film is patterned to leave the reflection film 23 separately on the inner side surface and the bottom surface of the package 22.

Next, gold bumps 25 are formed by a ball bonder on the semiconductor light emitting device 101, and the semiconductor light emitting device 101 is fixed onto a submount 24, which has electrodes patterned for the p-side electrode 4 and the n-side electrode 7. The submount 24 is placed on and fixed to the reflection film 23 on the bottom surface of the package 22. To fix them, bonding with adhesive and soldering can be used. Alternatively, the semiconductor light emitting device 101 can be directly fixed onto the submount 24 without using gold bumps 25 formed by a ball bonder.

Next, the n-side electrode and the p-side electrode, not shown, on the submount 24 are connected through bonding wires 26 to electrodes, not shown, provided on the package 22.

Furthermore, a first phosphor layer 211 containing red phosphor is formed so as to cover the semiconductor light emitting device 101 and the bonding wires 26. On the first phosphor layer 211 is formed a second phosphor layer 212 containing at least any of blue, green, and yellow phosphor.

To form each phosphor layer, a raw resin liquid mixture dispersed with the phosphor is dropped, and then subjected to thermal polymerization by heat treatment to cure the resin. If the raw resin liquid mixture containing each phosphor is cured after it is dropped and left standing for a while, fine particles of the phosphor can be precipitated and biased toward the downside of the first and second phosphor layer 211, 212. Thus, the light emission efficiency of each phosphor can be controlled as appropriate. Then, a lid 27 is provided on the phosphor layers. Thus, the semiconductor light emitting apparatus 201, namely, a white LED according to this embodiment is fabricated.

The embodiments of the invention have been described with reference to the examples. However, the invention is not limited thereto. The shape, size, material, and layout of the elements constituting the semiconductor light emitting device such as the semiconductor multilayer film, metal film, and dielectric film, as well as the crystal growth process, can be variously modified by those skilled in the art without departing from the spirit of the invention, and any such modifications are also encompassed within the scope of the invention. Furthermore, an appropriate combination of a plurality of components disclosed in the above examples can constitute various inventions. For example, some components may be omitted from the entire components shown in each example. Furthermore, components can be suitably combined with each other across different examples.

The “nitride semiconductor” referred to herein includes semiconductors having any composition represented by the chemical formula BₓIn_{y}Al_{z}Ga_{1-x-y—}N (0≦x≦1, 0≦y≦1, 0≦x≦1, x+y+z≦1) where the composition ratios x, y, and z are varied in the respective ranges. Furthermore, the “nitride semiconductor” also includes those, in the above chemical formula, further containing any group V element other than N (nitrogen), and any of various dopants added for controlling conductivity types.

The embodiments of the invention have been described with reference to the examples. However, the invention is not limited thereto. For example, shape, size, material, configuration and the like of each element such as a semiconductor multi-layer film, a metal film, a dielectric film constituting a semiconductor light emitting device and a semiconductor light emitting apparatus, and phosphors, and the method for manufacturing that are suitably selected from the publicly known ones by those skilled in the art are encompassed within the scope of the invention as long as the invention can be implemented similarly and the same effects can be achieved.

Components in two or more of the specific examples can be combined with each other as long as technically feasible, and such combinations are also encompassed within the scope of the invention as long as they fall within the spirit of the invention.

All semiconductor light emitting devices and semiconductor light emitting apparatuses described above as the embodiment of the invention can be suitably modified and practiced by those skilled in the art, and such modifications are also encompassed within the scope of the invention as long as they fall within the spirit of the invention.

Various other variations and modifications can be conceived by those skilled in the art within the spirit of the invention, and it is understood that such variations and modifications are also encompassed within the scope of the invention.

1-18. (canceled)

19. A semiconductor light emitting device comprising:
a substrate;
a buffer layer provided on the substrate and including at least one of AlN and AlₓGa₁₋ₓN (0.8≦x≦1), the buffer layer including
a first buffer layer provided on the substrate, and
a second buffer layer provided on the first buffer layer, a carbon concentration in the first buffer layer being higher than a carbon concentration in the second buffer layer,
a laminated structure body provided on the buffer layer, the laminated structure body including
an n-type semiconductor layer provided on the buffer layer,
a light emitting layer provided on the n-type semiconductor layer, and
a p-type semiconductor layer provided on the light emitting layer;
a first electrode connected to the n-type semiconductor layer and containing at least one of silver and a silver alloy; and
a second electrode connected to the p-type semiconductor layer,
the n-type semiconductor layer including a contact layer in contact with the first electrode, a Si concentration in the contact layer being not less than 1.1×10¹⁹ cm⁻³ and not more than 3.0×10¹⁹ cm⁻³.

20. The device according to claim 19, wherein
the laminated structure body has a first major surface on a side of the p-type semiconductor layer,
the first electrode is provided on the first major surface side of the laminated structure body, and
the second electrode is provided on the first major surface side of the laminated structure body.

21. The device according to claim 20, wherein the substrate is made of sapphire.

22. The device according to claim 19, wherein a peak emission wavelength of a light emitted from the light emitting layer is in the range of 370 to 400 nm.

23. The device according to claim 19, wherein the first electrode contains aluminum.

24. The device according to claim 23, wherein an aluminum composition ratio of the first electrode on a side of the n-type semiconductor layer is higher than on a side opposite to the n-type semiconductor layer.

25. The device according to claim 19, wherein the second electrode contains at least one of silver and a silver alloy.

26. The device according to claim 19, wherein the second electrode includes a platinum layer, a silver layer provided between the platinum layer and the p-type semiconductor layer, and a platinum thin film provided on an interface between the silver layer and the p-type semiconductor layer by diffusion from the platinum layer.

27. The device according to claim 19, wherein the second electrode is transparent to a light emitted from the light emitting layer.

28. The device according to claim 19, wherein the carbon concentration in the first buffer layer is not less than 3×10¹⁸ cm⁻³ and not more than 5×10²⁰ cm⁻³.

29. The device according to claim 28, wherein the carbon concentration in the second buffer layer is not less than 1×10¹⁶ cm ³ and not more than 3×10¹⁸ cm³.

30. The device according to claim 29, wherein the buffer layer further includes a third buffer layer made of non-doped GaN.

31. The device according to claim 29, wherein a surface roughness on the second buffer layer is smaller than a lattice constant of the second buffer layer.

32. The device according to claim 19, wherein
the n-type semiconductor layer further includes a n-type layer provided between the buffer layer and the contact layer,
a Si concentration in the n-type layer is lower than the Si concentration in the contact layer.

33. The device according to claim 32, wherein the Si concentration in the n-type layer is not less than 1×10¹⁸ cm⁻³and not more than 5×10¹⁸ cm ³.

34. The device according to claim 19, wherein the first electrode includes Ag and Pd, and the second electrode includes Ag and Pt.

35. The device according to claim 19, wherein the first electrode includes a layer of silver and the second electrode includes a layer of a silver alloy.

36. The device according to claim 19, wherein the first electrode includes a layer of a silver alloy and the second electrode includes a layer of silver.

37. The device according to claim 19, wherein the first electrode includes a first silver alloy, the second electrode contains a second silver alloy, and a composition of the first silver alloy is different from a composition of the second silver alloy.

38. The device according to claim 20, wherein
the p-type semiconductor layer and the light emitting layer are selectively removed and part of the n-type semiconductor layer is exposed to the first major surface.

39. The device according to claim 19, wherein the buffer layer is single crystal.
